(19) United States
(12) Patent Application Publication
(10) Pub. No.: US 2007/0072387 A1
(43) Pub. Date: Mar. 29, 2007

(54) METHOD OF FABRICATING SHALLOW TRENCH ISOLATION STRUCTURE

(76) Inventors: Su-Chen Lai, Chiayi City (TW); Chia-Shun Hsiao, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/164,546

(22) Filed: Nov. 29, 2005

(30) Foreign Application Priority Data
Sep. 28, 2005 (TW) 94133683

(51) Int. Cl. H01L 21/76

(52) U.S. Cl. 438/424; 438/426; 438/428

(57) ABSTRACT

A method of fabricating a shallow trench isolation structure is provided. A substrate having a patterned pad layer is provided. A part of the substrate is removed by using the patterned pad layer as a mask and a trench is thus formed in the substrate. A first insulation layer is formed on the substrate, the patterned pad layer and the trench. A second insulation layer is formed on the first insulation layer and partially fills into the trench. A third insulation layer is formed on the substrate and fills in the trench. The third insulation layer on the patterned pad layer and the patterned pad layer are removed subsequently.

### CROSS-REFERENCE TO RELATED APPLICATION

This application claims the priority benefit of Taiwan application serial no. 94133683, filed on Sep. 28, 2005. All disclosure of the Taiwan application is incorporated herein by reference.

### BACKGROUND OF THE INVENTION

1. Field of the Invention

The present invention relates to a method of fabricating a semiconductor component, and more particularly, to a method of fabricating a shallow trench isolation structure.

2. Description of the Related Art

Along with the improvement of semiconductor technology, the scale of the semiconductor component continuously decreases and steps into the sub micron field or even a smaller scale range. Accordingly, the isolation between components becomes a very important issue as the isolation can effectively prevent the neighboring components from being short circuited. In general, a local oxidation of silicon (LOCOS) method is commonly used to add an insulation layer between the components. However, the LOCOS method has some disadvantages such as the problems related to the stress, or the bird's beak formed on the periphery of the isolation structure. Wherein, the bird's beak is a major obstacle that prevents the integrity of the component from further improving. Consequently, the most popular method used in the industry is the shallow trench isolation (STI) fabricating process.

FIGS. 1A˜1B are the schematic sectional views illustrating a conventional process of fabricating a shallow trench isolation structure. First, referring to FIG. 1A, a substrate 100 is provided. Then, a patterned pad layer 102 is formed on the substrate 100, and a trench 104 is formed in the substrate 100 by using the patterned pad layer 102 as a mask. Then, a liner layer 106 is formed on the surface of the trench 104, and an insulation layer 108 is formed on the substrate 100 and fills with the trench 104.

Then, referring to FIG. 1B, a part of the insulation layer 108 is removed by an etching process, such that the height of the insulation layer 108 is lower than the surface of the substrate 100, and an insulation layer 108a is formed. Then, an oxide layer 110 is formed in the trench 104 by using a high density plasma chemical vapor deposition (HDP CVD) process.

However, the side surface of the patterned pad 102, the substrate 100 and the liner layer 106 at the corner 112 of the trench 104 are commonly damaged while removing part of the insulation layer 108 by using the etching process. After the shallow trench isolation structure is totally completed, the current leakage easily occurs on the corner 112, which causes the problem of short circuit. Accordingly, the reliability of the components is impacted and the yield rate of the components is deteriorated.

In addition, since the depth of the insulation layer 108 that can be removed by the etching process is limited, the H/W (height/width) ratio of the etched space is too small. In other words, the depth of the insulation layer 108 etched by the etching process is too shallow, such that the thickness of the oxide layer 110 filled by the subsequent HDP CVD process is not thick enough, thus it is hard to sustain it.

Accordingly, how to prevent the side surface of the patterned pad 102, the substrate 100 and the liner layer 106 at the corner 112 of the trench 104 from being damaged and how to increase the thickness of the oxide layer 110 are the main subjects to be resolved by the present invention.

### SUMMARY OF THE INVENTION

Therefore, it is an object of the present invention to provide a method of fabricating a shallow trench isolation structure for preventing the side surface of the patterned pad, the substrate and the liner layer at the corner of the trench from being damaged.

It is another object of the present invention to provide a method of fabricating a shallow trench isolation structure. An insulation layer is formed on the bottom of the trench, so as to decrease the H/W ratio of the trench, such that a sufficient space is reserved for forming another insulation layer.

The present invention provides a method of fabricating a shallow trench isolation structure. A substrate having a patterned pad layer is provided. A part of the substrate is removed by using the patterned pad layer as a mask and a trench is thus formed in the substrate. A first insulation layer is formed on the substrate, the patterned pad layer and the trench. A second insulation layer is formed on the first insulation layer and partially fills into the trench. A third insulation layer is formed on the substrate and fills with the trench. The third insulation layer on the patterned pad layer and the patterned pad layer are removed subsequently.

The present invention further provides a method of fabricating a shallow trench isolation structure. First, a substrate having a trench is provided. Then, a first insulation layer is formed on the substrate, and the first insulation layer partially fills in the trench. Then, an annealing process is performed to re-flow the first insulation layer. Afterwards, the first insulation layer on the substrate is removed, and a second insulation layer is formed on the first insulation layer by using the HDP CVD process.

In the present invention, since the insulation layer, e.g. borophospho-silicate glass (BPSG), is merely formed on the bottom of the trench, a sufficient space is reserved for filling the insulation layer subsequently formed by the HDP CVD process without having to use the etching process to remove part of the insulation layer. In other words, the thickness of the insulation layer formed by the HDP CVD process is thick enough in the trench, thus it is easily sustained and the damages on the pad layer, the liner layer and the substrate due to the etching are eliminated. In addition, before the BPSG insulation layer is formed, an insulation layer made of silicon oxide may be formed, and this insulation layer can prevent the dopants (e.g. B (boron) or phosphorus (P)) from out-diffusing. Accordingly, the reliability and the yield rate of the components are improved.

### BRIEF DESCRIPTION OF THE DRAWINGS

The accompanying drawings are included to provide a further understanding of the invention, and are incorporated in and constitute a part of this specification. The drawings illustrate embodiments of the invention, and together with the description, serve to explain the principles of the invention.

FIGS. 1A˜1B are the schematic sectional views illustrating a conventional process of fabricating a shallow trench isolation structure.

FIGS. 2A˜2F are the schematic sectional views illustrating a process of fabricating a shallow trench isolation structure according to an embodiment of the present invention.

FIGS. 3A˜3D are the schematic sectional views illustrating a process of fabricating a shallow trench isolation structure according to another embodiment of the present invention.

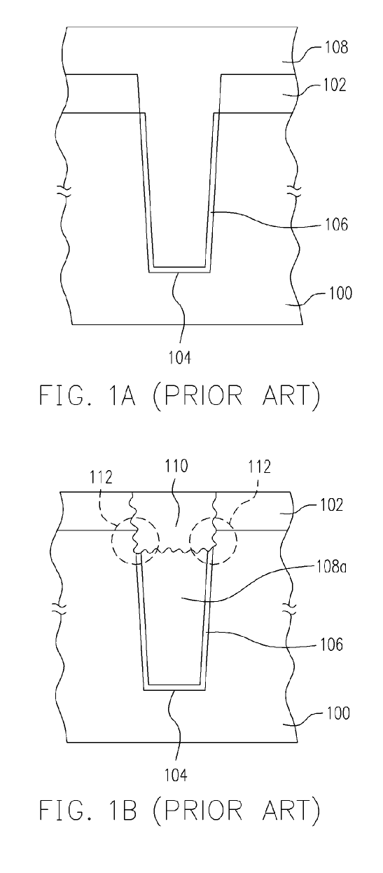

### DESCRIPTION OF PREFERRED EMBODIMENTS

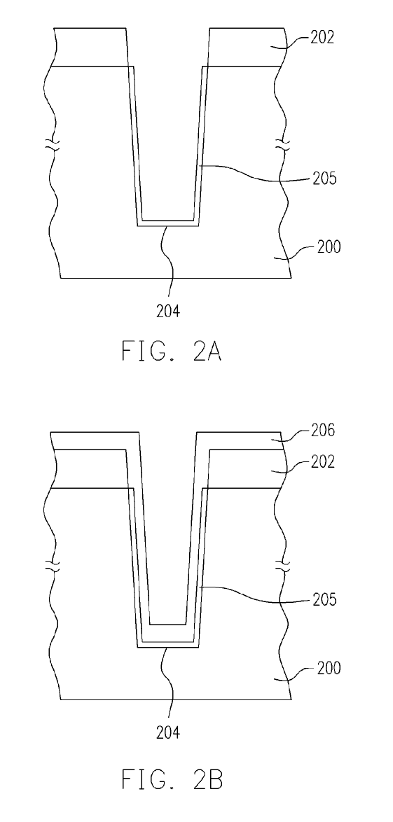

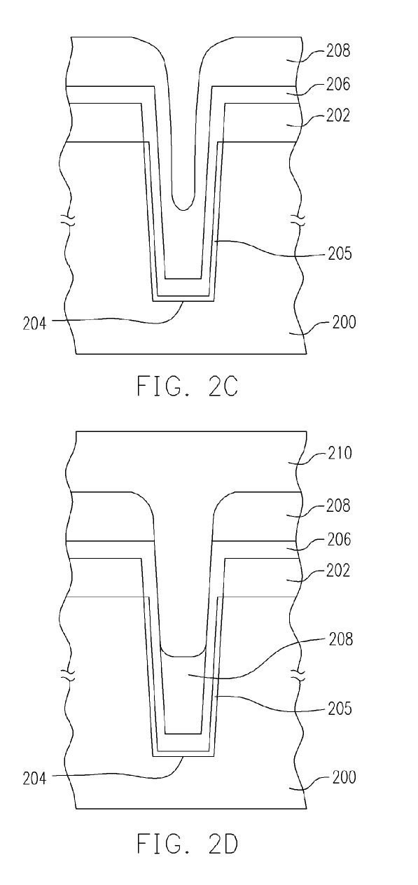

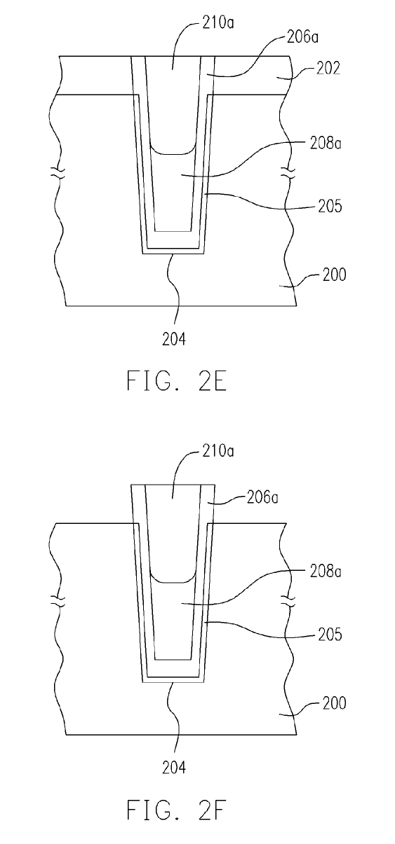

FIGS. 2A˜2F are the schematic sectional views illustrating a process of fabricating a shallow trench isolation structure according to an embodiment of the present invention. First, referring to FIG. 2A, a substrate 200 is provided. A pad layer (not shown) is formed on the substrate 200, wherein the pad layer may be made of silicon oxide and formed by the CVD process. The pad layer is patterned to form a patterned pad layer 202. Then, the patterned pad layer 202 is used as a mask to perform an etching process for removing a part of the substrate 200, such that a trench 204 is formed in the substrate 200. The etching may be an anisotropic etching. In addition to being used as the mask layer in the etching process, the patterned pad layer 202 can be used as a polish stop layer. Then, a liner layer 205 is formed on the surface of the trench 204, wherein the liner layer 205 may be made of silicon oxide and formed by thermal oxidation.

Referring to FIG. 2B, an insulation layer 206 is formed on the substrate 200, the patterned pad layer 202 and the surface of the trench 204. The insulation layer 206 may be made of silicon oxide, silicon nitride or silicon oxynitride, and may be formed by the CVD process.

Referring to FIG. 2C, an insulation layer 208 is formed on the insulation layer 206, and the insulation layer 208 partially fills in the trench 204. In other words, most of the insulation layer 208 is formed on the bottom of the trench 204, whereas a small portion of the insulation layer 208 is formed on the sidewall of the trench 204. Here, the insulation layer 208 is a reflowable oxide, such as the borophospho-silicate glass (BPSG), the phosphor-silicate glass (PSG) or the fluorinated silicate glass (FSG), and the insulation layer 208 may be formed by the CVD process. It is noted that since the insulation layer 206 has been formed before the insulation layer 208 is formed, the present embodiment can prevent the dopants of the insulation layer 208 from out-diffusing. However, the flatness of the insulation layer formed by the CVD process is rather poor, thus the gap is easily formed in the insulation layer. Therefore, after the CVD process, an annealing process can be performed to re-flow the insulation layer 208 for removing the gap, such that the surface of the insulation layer 208 will be flatter. Meanwhile, the insulation layer 208 on the sidewall of the trench 204 will flow to the bottom of the trench 204 as shown in FIG. 2D. In another embodiment, the insulation layer 208 may be made of spin-on-glass (SOG), and this material is coated on the insulation layer 206 by using a spin coating method, thus the gap is not generated and the surface is flatter.

Then, referring to FIG. 2D, an insulation layer 210 is formed on the substrate 200 and fills with the trench 204. The insulation layer 210 may be made of silicon oxide and formed by the HDP CVD process.

In an embodiment of the present invention, the depth of the trench 204 is about 3000˜5000 Å (angstroms), and the thickness of the insulation layer 208 formed on the bottom of the trench 204 is about 1500˜2500 Å, which is about ½˜⅔ height of the trench 204. In such case, a sufficient space is reserved in the trench 204 for subsequently filling the insulation layer 210. In other words, the insulation layer 210 subsequently filled into the trench 204 is thick enough, thus it is easy to be sustained. Moreover, since the insulation layer 208 has been filled into the trench 204 first, the H/W ratio of the trench for the insulation layer 210 is reduced. Thus, it can facilitate the filling of the insulation layer 210 and avoid the generation of voids therein.

Referring to FIG. 2E, the insulation layers 206, 208 and 210 on the patterned pad layer 202 are removed so as to form the insulation layers 206a, 208a and 210a. The insulation layers 206, 208 and 210 on the patterned pad layer 202 are removed by, for example, using a chemical mechanical polishing (CMP) technique, and the patterned pad layer 202 is used as a polish stop layer.

Then, referring to FIG. 2F, the patterned pad layer 202 is removed. The patterned pad layer 202 is removed by, for example, using a wet etching process, and the etching solution includes hot phosphoric acid.

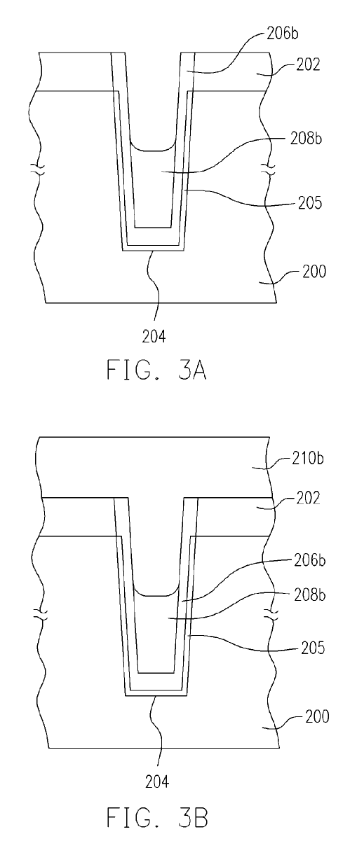

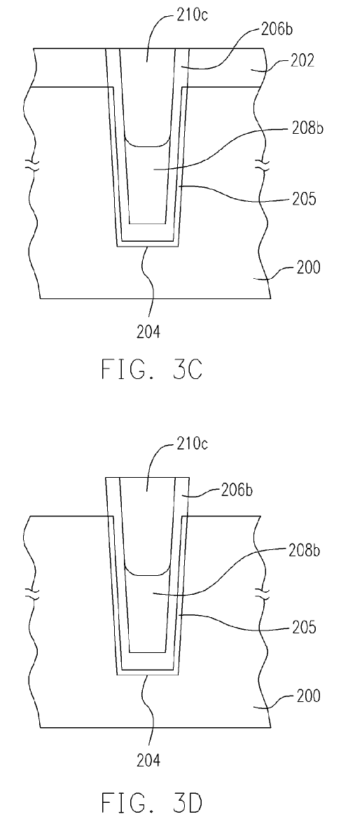

FIGS. 3A˜3D are the schematic sectional views illustrating a process of fabricating a shallow trench isolation structure according to another embodiment of the present invention. First, referring to FIG. 3A, a substrate 200 is provided. A patterned pad layer 202, a trench 204, a liner layer 205, an insulation layer 206 and an insulation layer 208 are formed on the substrate 200, and such layers are formed on the substrate 200 with the same method as described in FIGS. 2A˜2C, thus its detail is omitted herein. Then, the insulation layers 206 and 208 on the patterned pad layer 202 are removed so as to form the insulation layers 206b and 208b. The insulation layers 206 and 208 on the patterned pad layer 202 are removed by, for instance, using a chemical mechanical polishing (CMP) technique, and the patterned pad layer 202 is used as a polish stop layer.

Then, referring to FIG. 3B, an insulation layer 210b is formed on the substrate 200 and fills with the trench 204. Wherein, the insulation layer 210b may be made of silicon oxide and formed by using a HDP CVD process.

Referring to FIG. 3C, the insulation layer 210b on the patterned pad layer 202 is removed so as to form an insulation layer 210c. The insulation layer 210b on the patterned pad layer 202 is removed by, for instance, using the chemical mechanical polishing (CMP) technique, and the patterned pad layer 202 is used as the polish stop layer.

Referring to FIG. 3D, the patterned pad layer 202 is removed by using an etching process. For example, the patterned pad layer 202 is removed by using a wet etching process, and the etching solution is hot phosphoric acid.

In summary, since the insulation layer 208 is merely formed on the bottom of the trench 204, a sufficient space is reserved in the trench 204 for filling the insulation layer 210. Accordingly, the thickness of the insulation layer 210 subsequently filled into the trench 204 is thick enough, thus it is easy to be sustained. Moreover, there is no need to use the etching process to remove part of the insulation layer 208 in advance, and consequently the patterned pad layer 202, the liner layer 205 and the substrate 200 are prevented from being damaged during the etching process, such that the current leakage or short circuit problem is resolved. Moreover, the insulation layer 208 is filled into the trench 204 first, such that the H/W ratio of the region where the insulation layer 210 to be filled into is decreased. Hence, it will be easier to fill the insulation layer 210 into the trench 204. Furthermore, the insulation layer 206 can prevent the dopants in the insulation layer 208 from out-diffusing. Accordingly, the reliability and the yield rate of the resultant components are improved.

Although the invention has been described with reference to a particular embodiment thereof, it will be apparent to one of the ordinary skills in the art that modifications to the described embodiment may be made without departing from the spirit of the invention. Accordingly, the scope of the invention will be defined by the attached claims not by the above detailed description.

What is claimed is:

1. A method of fabricating a shallow trench isolation structure, comprising:
forming a patterned pad layer on a substrate;
removing a part of the substrate by using the patterned pad layer as a mask, so as to form a trench in the substrate;
forming a first insulation layer on the substrate, the patterned pad layer, and a surface of the trench;
forming a second insulation layer on the first insulation layer, and partially filling the trench with the second insulation layer;
forming a third insulation layer on the substrate, and filling the trench with the third insulation layer;
removing the third insulation layer on the patterned pad layer; and
removing the patterned pad layer.

2. The method of fabricating the shallow trench isolation structure of claim 1, wherein the second insulation layer comprises an oxide formed by using a chemical vapor deposition (CVD) process.

3. The method of fabricating the shallow trench isolation structure of claim 2, wherein the second insulation layer comprises a borophospho-silicate glass (BPSG), a phosphor-silicate glass (PSG), or a fluorinated silicate glass (FSG).

4. The method of fabricating the shallow trench isolation structure of claim 1, wherein the second insulation layer is a spin-on-glass (SOG).

5. The method of fabricating the shallow trench isolation structure of claim 1, wherein a thickness of the second insulation layer partially filled in the trench is about ½˜⅔ height of the trench.

6. The method of fabricating the shallow trench isolation structure of claim 1, wherein the first insulation layer is silicon oxide, silicon nitride, or silicon oxynitride.

7. The method of fabricating the shallow trench isolation structure of claim 1, wherein the first insulation layer is formed by using a chemical vapor deposition (CVD) process.

8. The method of fabricating the shallow trench isolation structure of claim 1, wherein the third insulation layer is formed by using a high density plasma chemical vapor deposition (HDP CVD) process.

9. The method of fabricating the shallow trench isolation structure of claim 1, further comprising forming a liner layer between the surface of the trench and the first insulation layer.

10. The method of fabricating the shallow trench isolation structure of claim 1, further comprising removing the first insulation layer and the second insulation layer on the patterned pad layer prior to forming the third insulation layer.

11. The method of fabricating the shallow trench isolation structure of claim 1, further comprising performing an annealing process to re-flow the second insulation layer after the second insulation layer is formed.

12. A method of fabricating a shallow trench isolation structure, comprising:
providing a substrate having a trench formed therein;
forming a first insulation layer on the substrate and partially filling the first insulation layer into the trench;
performing an annealing process to re-flow the first insulation layer;
removing the first insulation layer on the substrate; and
forming a second insulation layer on the first insulation layer by using a high density plasma chemical vapor deposition (HDP CVD) process.

13. The method of fabricating the shallow trench isolation structure of claim 12, wherein the first insulation layer comprises an oxide formed by using a chemical vapor deposition (CVD) process.

14. The method of fabricating the shallow trench isolation structure of claim 13, wherein the first insulation layer comprises a borophospho-silicate glass (BPSG), a phosphor-silicate glass (PSG), or a fluorinated silicate glass (FSG).

15. The method of fabricating the shallow trench isolation structure of claim 12, wherein the first insulation layer is a spin-on-glass (SOG).

16. The method of fabricating the shallow trench isolation structure of claim 12, wherein a thickness of the first insulation layer partially filled into the trench is about ½˜⅔ height of the trench.

17. The method of fabricating the shallow trench isolation structure of claim 12, further comprising forming a third insulation layer on a sidewall surface of the trench before forming the first insulation layer.

18. The method of fabricating the shallow trench isolation structure of claim 17, wherein the third insulation layer is formed by using a chemical vapor deposition (CVD) process.

19. The method of fabricating the shallow trench isolation structure of claim 12, further comprising forming a liner layer between a surface of the trench and the first insulation layer.

20. The method of fabricating the shallow trench isolation structure of claim 12, wherein removing the first insulation layer on the substrate comprises performing a chemical mechanical polishing (CMP) process.
